(19) United States
(12) Patent Application Publication
(10) Pub. No.: US 2007/0052069 A1
(43) Pub. Date: Mar. 8, 2007

(54) Integrated conductor arrangement and corresponding production method

(76) Inventors: Martin Gutsche, Dorfen (DE); Harald Seidl, Poring (DE)

Correspondence Address: JENKINS, WILSON, TAYLOR & HUNT, P. A., 3100 TOWER BLVD, SUITE 1200, DURHAM, NC, 27707, US

(21) Appl. No.: 11/362,384

(22) Filed: Feb. 24, 2006

(30) Foreign Application Priority Data
Mar. 8, 2005 (DE) 102005010513.0

(51) Int. Cl. H01L 29/40; G08B 13/14

(52) U.S. Cl. 257/664; 340/572.7; 257/698; 257/E23.067

(57) ABSTRACT

An integrated conductor arrangement comprises a substrate with a top side, at least one tubular conductor trench provided in the substrate below the top side of the substrate and a conductor. The conductor comprises at least one tubular conductor layer and is integrated in the conductor trench.

### BACKGROUND OF THE INVENTION

1. Field of the Invention

The present invention relates to an integrated conductor arrangement, in particular a coaxial conductor arrangement, and a corresponding production method.

2. Description of the Prior Art

Without restricting the generality, the problem area on which the present invention is based is discussed with reference to coaxial conductors.

Radio frequency cables are designed as waveguides for radio frequency signal transmission which are employed at frequencies of typically up to 2 GHz.

A customary coaxial cable is a double line comprising two coaxial cylinders having a circular cross section. It comprises one or more coaxial pairs, in each coaxial pair the inner conductor, the dielectric, the outer conductor and the sheath being arranged coaxially. Advantages of coaxial cables are that no energy is radiated, and there is a relative insensitivity toward incident radiation.

### SUMMARY OF THE INVENTION

It is an object of the present invention to provide an integrated conductor arrangement, in particular a coaxial conductor arrangement, and a corresponding production method which make it possible to produce integrated, in particular coaxially arranged and shielded, conductors on the chip.

The object is achieved in accordance with the invention by means of an integrated conductor arrangement, comprising:

a substrate;

at least one tubular conductor trench provided in the substrate below the top side of the substrate; and

a conductor, in particular coaxial conductor, integrated in the conductor trench;

the conductor having at least one tubular conductor layer.

The object is also achieved in accordance with the invention by means of a method for producing an integrated arrangement, comprising the steps of:

providing a substrate;

providing a patterned mask layer on the top side of the substrate;

etching a conductor trench and an adjoining contact trench, which has a larger diameter than the conductor trench, in the substrate using the patterned mask layer;

undercutting the patterned mask layer in order to form an expanded conductor trench and an adjoining expanded contact trench;

depositing an insulating outer insulator layer over the patterned mask layer, as result of which the walls of the expanded conductor trench and of the adjoining expanded contact trench are covered with the insulating outer insulator layer and the patterned mask layer is closed off in the region of the expanded conductor trench and remains open in the region of the expanded contact trench; and

depositing an at least one conductor layer, in particular successively depositing a conductive outer conductor layer, an insulating middle insulator layer and a conductive inner conductor layer in order to form a conductor, in particular a coaxial conductor, integrated in the conductor trench.

The idea on which the present invention is based consists in applying a deposition method, e.g. an ALD (Atomic Layer Deposition) deposition method, with the aid of which it is possible to uniformly coat long cavities of the substrate from the inside.

Consequently, conductors, in particular coaxial conductors, can be produced by first forming long tubelike channels in the substrate, which are open only at their ends and in which at least one conductor, preferably an outer conductor, an insulation and an inner conductor are formed progressively by the deposition method.

The arrangement of the tubelike channels in the substrate is arbitrary, that is to say a vertical (in particular through the chip), horizontal or arbitrarily angular course is conceivable. It is also possible, if necessary, for more than two conductors to be interleaved in one another.

The conductive outer conductor layer, the insulating middle insulator layer and the conductive inner conductor layer may be in each case closed annularly.

An insulating outer insulator layer may be provided between the conductive outer conductor layer and the substrate.

A contact trench (or hole) having a larger diameter than the conductor trench may be provided at at least one end of the conductor trench, the coaxial conductor being led through the contact trench to the top side of the substrate.

A contact trench having a larger diameter than the conductor trench may be provided at at least one end of the conductor trench, the conductive inner conductor layer being led through the contact trench to the top side of the substrate, and the conductive outer conductor layer being led from the conductor trench to the top side of the substrate.

### DESCRIPTION OF THE DRAWINGS

FIG. 1 is a schematic illustration of a trench structure for a first exemplary integrated conductor arrangement, in plan viewer.

FIGS. 2A-H are schematic sectional illustrations of successive method stages of a method for producing an integrated conductor arrangement, in particular coaxial conductor arrangement, in accordance with the first embodiment of the present invention, to be precise in each case along the line A-A′ and B-B′ in FIG. 1.

FIGS. 3A-F are schematic sectional illustrations of successive method stages of a method for producing an integrated conductor arrangement, in particular coaxial conductor arrangement, in accordance with a second embodiment of the present invention, to be precise in each case along the line A-A′ and B-B′ in FIG. 1.

### DESCRIPTION OF THE PREFERRED EMBODIMENTS

In the figures, identical reference symbols designate identical or functionally identical component parts.

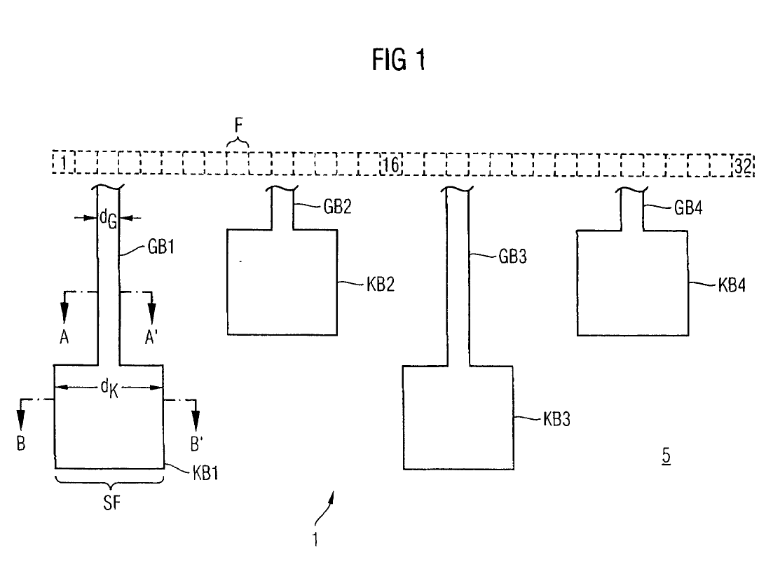

FIG. 1 shows a schematic illustration of a trench structure for an integrated conductor arrangement, in particular coaxial conductor arrangement, in accordance with a first embodiment of the present invention in plan view.

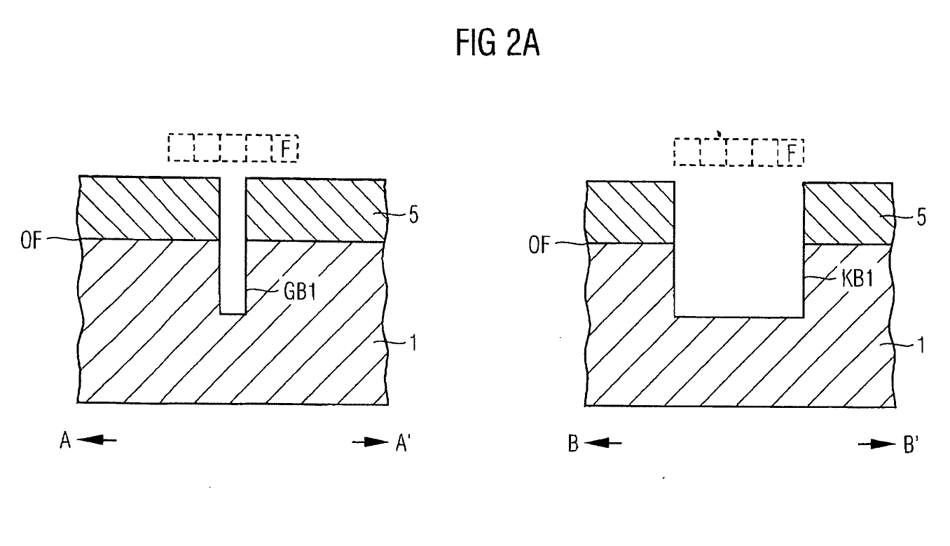

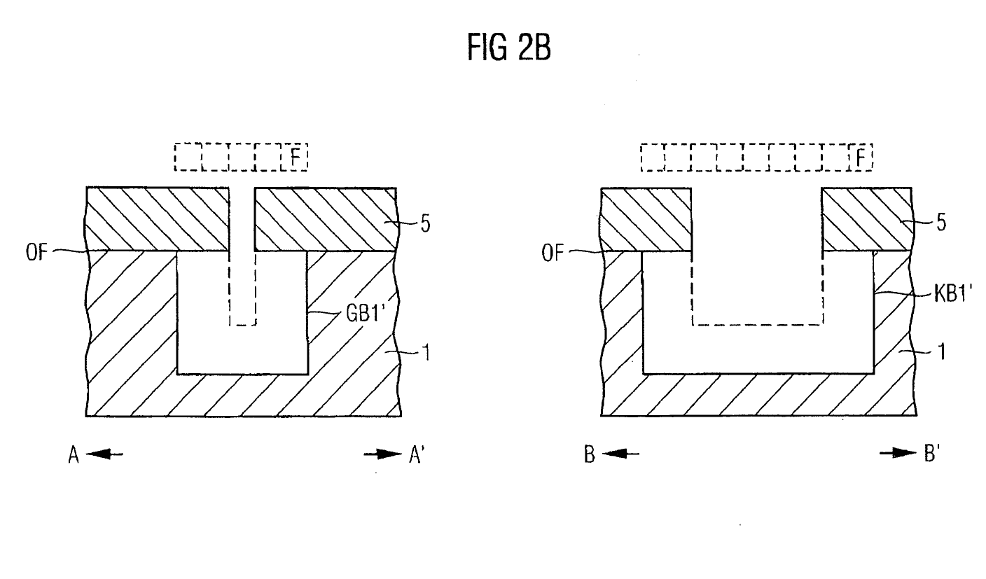

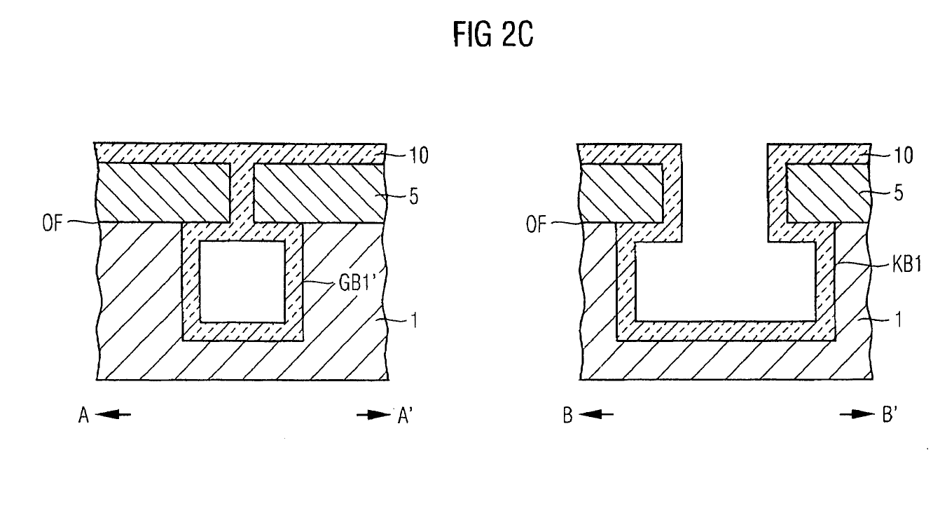

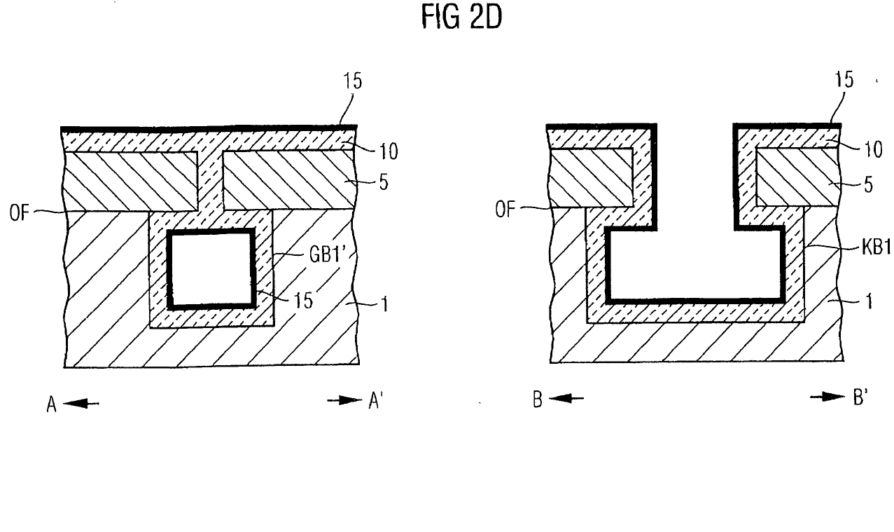

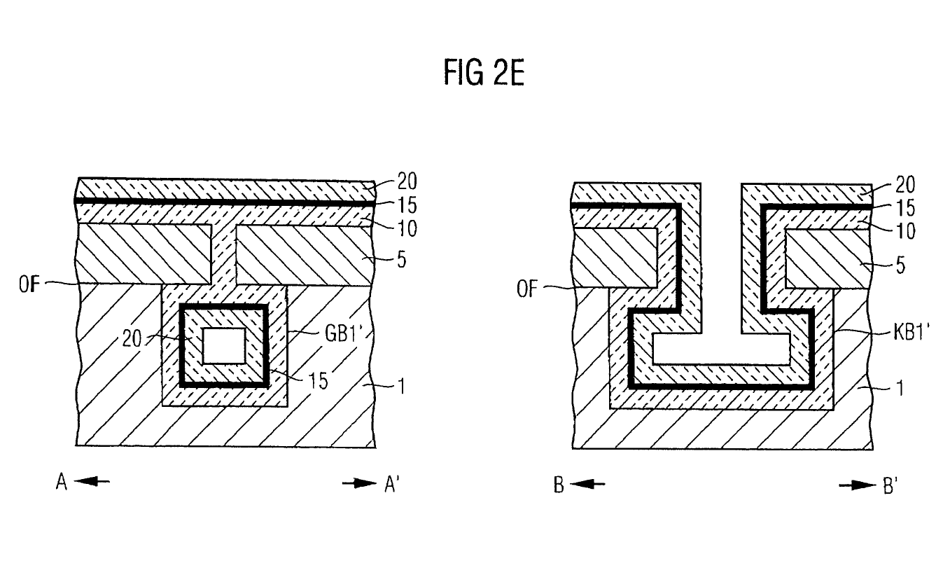

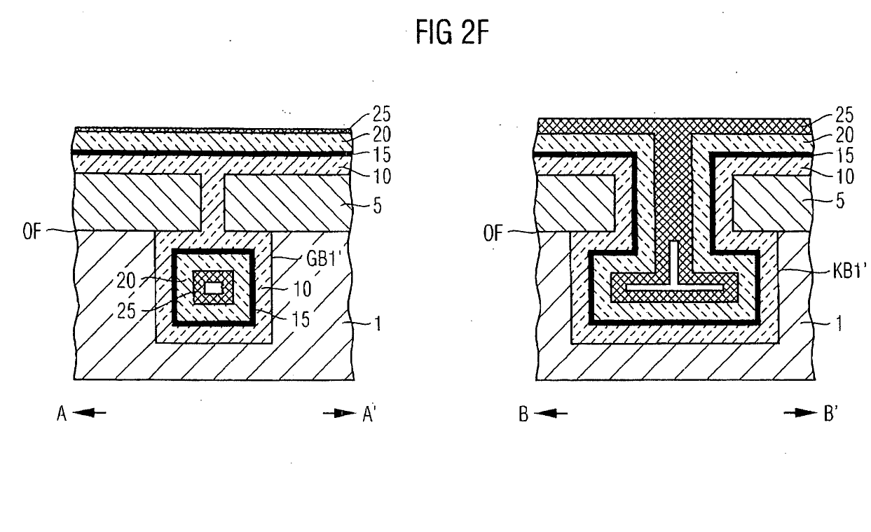

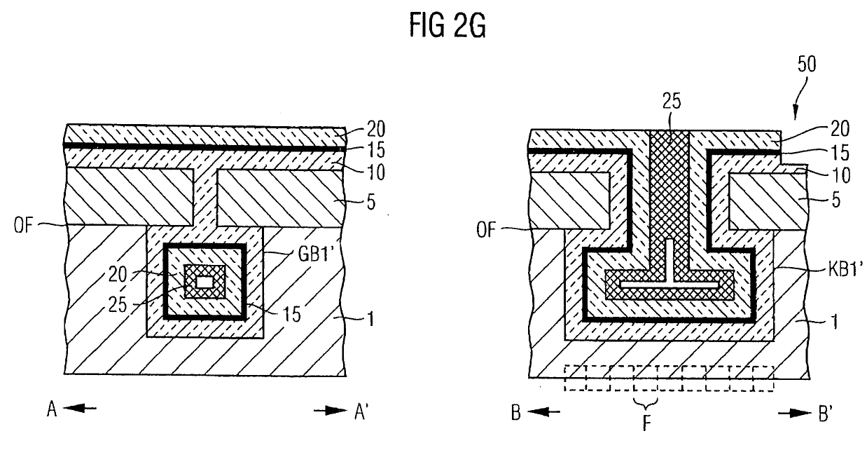

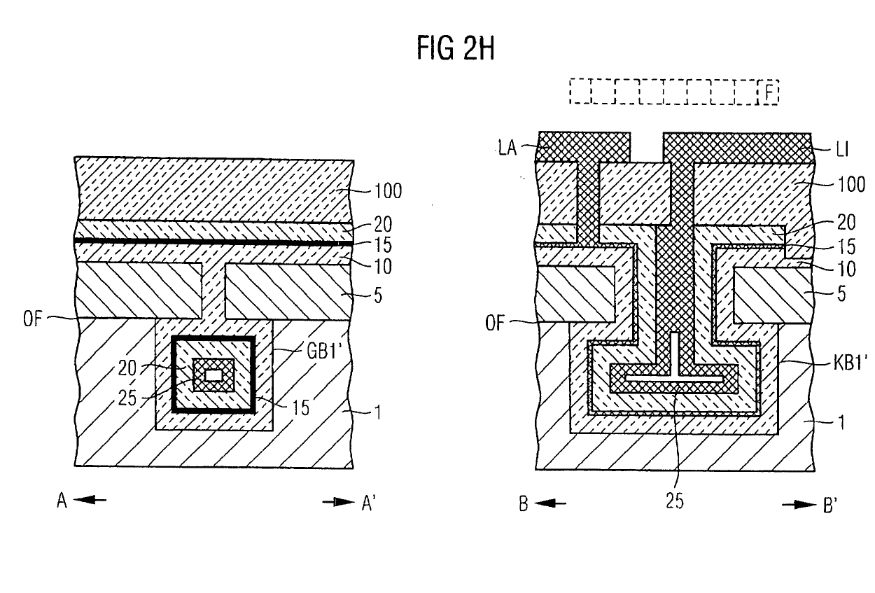

In FIG. 1, reference symbol 1 designates a silicon semiconductor substrate, on the top side OF (cf. FIG. 2) of which a patterned mask layer 5 made of silicon nitride, for example, is provided, which mask layer has openings for defining conductor trenches GB1 to GB4 and adjoining contact trenches KB1 to KB4. The diameter of the conductor trenches GB1 to GB4 is illustrated by the reference symbol d_{G} in FIG. 1 and is significantly smaller than the diameter d_{K} of the contact trenches KB1 to KB4.

As a scale for this, the upper region of FIG. 1 illustrates a scale whose smallest unit F represents the minimum feature size that can be obtained by means of the technology.

Consequently, the contact trenches KB1 to KB4 in FIG. 1 have a diameter of 5 F, whereas the conductor trenches GB1 to GB4 have a diameter of 1 F.

In FIG. 1, the contact trenches KB1 to KB4 are in each case depicted only at one end of the conductor trenches GB1 to GB4. It goes without saying that further contact trenches may also be situated at the other end or at arbitrary locations laterally with respect to the conductor trenches GB1 to GB4 or be distributed or arranged arbitrarily over the length of the conductor trenches.

FIGS. 2A-H show schematic sectional illustrations of successive method stages of a method for producing an integrated conductor arrangement, in particular coaxial conductor arrangement, in accordance with the first embodiment of the present invention, to be precise in each case along the line A-A′ and B-B′ in FIG. 1.

FIGS. 2A to 2H in each case illustrate on the left-hand side a section along the line A-A′ and on the right-hand side B-B′ as depicted in FIG. 1.

The process state illustrated in FIG. 2A corresponds to the process state in accordance with FIG. 1. With the aid of the patterned mask layer 5 made of silicon nitride or some other material, the conductor trench GB1 and the contact trench KB1 have been etched into the substrate 1 by means of an anisotropic etching method.

Referring further to FIG. 2B, the substrate 1 is then etched isotropically under the patterned mask layer 5 in order to form an expanded conductor trench GB1′ and an expanded contact trench KB1′. The degree of expansion can be inferred from the broken line indicated in each case in FIG. 2B, said line indicating the structure prior to the isotropic etching step.

In a subsequent method step illustrated in FIG. 2C, an insulating outer insulator layer 10 is then deposited over the structure, as a result of which the walls of the expanded conductor trench GB1′ and of the adjoining expanded contact trench KB1′ are covered with the insulating outer insulator layer 10 and as a result of which the patterned mask layer 5 is closed off in the region of the expanded conductor trench GB1′ and remains open in the region of the expanded contact trench KB1′. Consequently, long tubelike channels are formed in the substrate 1, which are also closed off at the top and in which later the coaxial conductor runs.

Afterward, in accordance with FIG. 2D, a conductive outer conductor layer 15 is deposited conformally by means of an ALD method in such a way that it covers the walls of the extended conductor trench GB1′ and of the extended contact trench KB1′.

Referring further to FIG. 2E, an insulating middle insulator layer 20 is likewise deposited conformally by means of the ALD method, which layer is composed of silicon oxide, for example.

Referring to FIG. 2F, an ALD deposition of a conductive inner conductor layer 25 is then effected in order to complete the coaxial conductor which is integrated in the conductor trench GB1′ and has the layers 10, 15, 20, and 25.

In the process step illustrated in FIG. 2G, the conductive inner conductor layer 25 is then removed as far as the top side of the insulating middle insulator layer 20 on the top side of the structure, for example by means of a chemical mechanical polishing step or an RIE (Reactive Ion Etching) etching-back step. A depression 50 is subsequently formed at the top side of the structure, through which a part of the conductive outer conductor layer 15 is removed, as a result of which the conductive outer conductor layer 15 is patterned.

Referring further to FIG. 2H, a further insulation layer 100 is deposited over the resulting structure, and the conductive inner conductor layer 25 and the conductive outer conductor layer 15 are subsequently contact-connected with a respective conductor track LI and LA.

Although the conductor tracks LI, LA are depicted as non-shielded in the present example, it is possible, of course, also to shield these conductor tracks on the surface of the substrate.

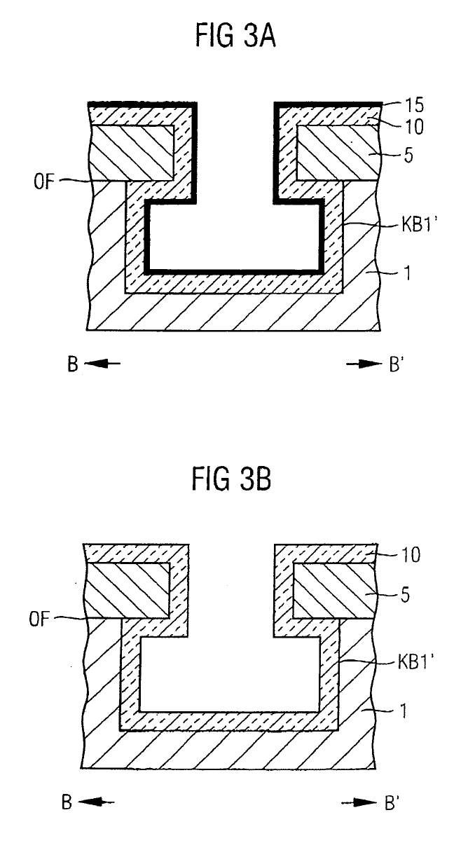

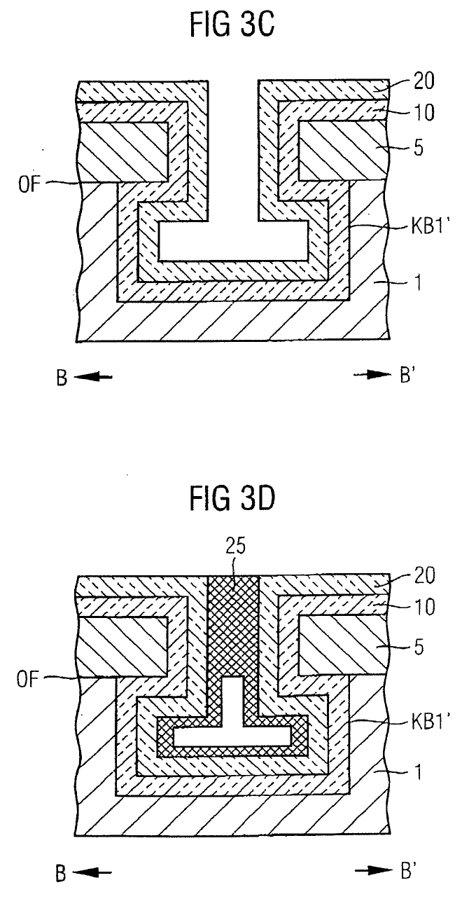

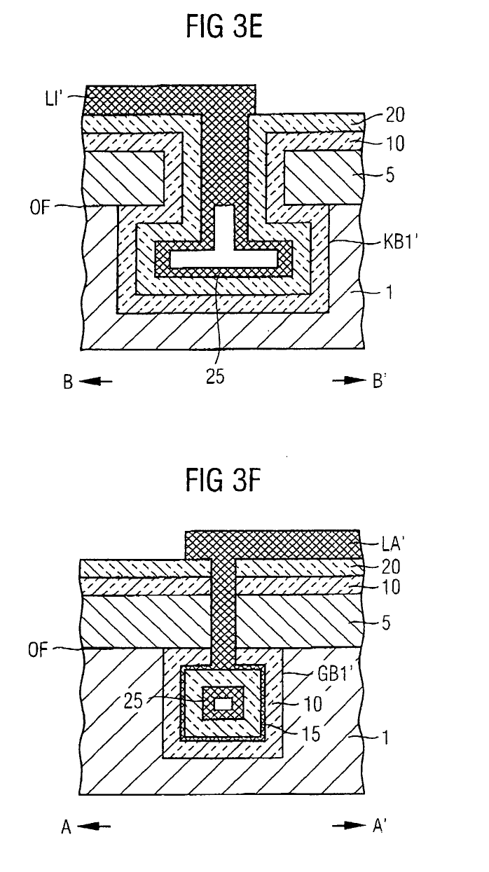

FIGS. 3A-F show schematic sectional illustrations of successive method stages of a method for producing an integrated conductor arrangement, in particular coaxial conductor arrangement, in accordance with a second embodiment of the present invention, to be precise in each case along the line A-A′ and B-B′ in FIG. 1.

In the second embodiment of the production method according to the invention, the starting point in accordance with FIG. 3A is the same state as the state in accordance with FIG. 2D (right-hand side).

In this second exemplary embodiment, however, the conductive outer conductor layer 15 is removed in the region of the contact trench KB1′ prior to deposition of the insulating middle insulator layer 20 and the conductive inner conductor layer 25, as can be gathered from FIG. 3B (isotropic etching which, however, does not reach into the conductor trench). Consequently, as illustrated in FIG. 3C and FIG. 3D, in the region of the contact trench KB1′ only the conductive inner conductor layer 25 is led to the top side OF of the substrate 1, where it is contact-connected by a conductor track LI′ in accordance with FIG. 3E.

The conductive outer conductor layer 15, by contrast, is contact-connected by a conductor track LA′ in the region of the conductor trench GB1′, to be precise after the outer insulator layer 10 has been removed in the through-plating region.

Since the opening that remains in the contact trench KB1′ at the top side is greater than in the case of the first exemplary embodiment, the deposition of the conductive inner conductor layer 25 is firstly carried out with high conformity, after which the conformity is lowered at the end in order to deposit the material with poorer edge coverage, so that it is possible to close the contact trench KB1′ with the conductive inner conductor layer 25.

Although the present invention has been described above on the basis of a preferred exemplary embodiment, it is not restricted thereto, but rather can be modified in diverse ways.

In particular, the invention can be applied in principle to arbitrary trench structures and material combinations.

The geometry of the contact holes can be chosen as desired, in particular also round or oval. Moreover, relative sizes other than those illustrated are possible.

Although modifications and changes may be suggested by those skilled in the art, it is the intention of the inventors to embody within the patent warranted heron all changes and modifications as reasonably and properly come within the scope of their contribution to the art.

We claim as our invention:

1. An integrated conductor arrangement, comprising:
a substrate with a top side;
at least one tubular conductor trench provided in said substrate below said top side of said substrate; and
a conductor comprising at least one tubular conductor layer and being integrated in said conductor trench.

2. The integrated conductor arrangement of claim 1, wherein said conductor is a coaxial conductor having a layer sequence comprising at least one conductive outer conductor layer, an insulating middle insulator layer and a conductive inner conductor layer.

3. The integrated conductor arrangement of claim 2, wherein each of said conductive outer conductor layer, said insulating middle insulator layer and said conductive inner conductor layer, is closed annularly.

4. The integrated conductor arrangement of claim 2, comprising an insulating outer insulator layer provided between said conductive outer conductor layer and said substrate.

5. The integrated conductor arrangement of claim 1, comprising a contact trench having a larger diameter than said conductor trench at at least one end of said conductor trench, said conductor being led through said contact trench to said top side of said substrate.

6. The integrated conductor arrangement of claim 2, comprising a contact trench having a larger diameter than said conductor trench at at least one end of said conductor trench; said conductive inner conductor layer being led through said contact trench to said top side of said substrate and said conductive outer conductor layer being led from said conductor trench to said top side of said substrate.

7. A method for producing an integrated conductor arrangement, comprising the steps of:
providing a substrate with a top side;
providing a patterned mask layer on said top side of said substrate;
etching a conductor trench and a contact trench having a larger diameter than said conductor trench in said substrate using said patterned mask layer; said conductor trench adjoining said contact trench;
undercutting said patterned mask layer in order to form an expanded conductor trench from said conductor trench and an expanded contact trench from said contact trench;
depositing an insulating outer insulator layer over said patterned mask layer so that walls of said expanded conductor trench and of said expanded contact trench are covered with said insulating outer insulator layer and so that said patterned mask layer is closed off in a region about said expanded conductor trench and remains open in said region of said expanded contact trench; and
depositing at least one conductor layer, an insulating middle insulator layer, and a conductive inner conductor layer in order to form a conductor integrated in said conductor trench.

8. The method of claim 7, wherein said conductor is led through said contact trench to said top side of said substrate.

9. The method according of claim 7, comprising removing said conductive outer conductor layer in said contact trench prior to depositing said insulating middle insulator layer and said conductive inner conductor layer; said conductive inner conductor layer being led through said contact trench to said top side of said substrate and said conductive outer conductor layer being led from said conductor trench to said top side of said substrate.

10. The method of claim 7, comprising removing said conductive inner conductor layer up to a top side of said insulating middle insulator layer after the depositing step, and connecting subsequently said conductive inner conductor layer and said conductive outer conductor layer with a respective conductor track.

11. The method of claim 7, wherein during depositing said conductive inner conductor layer and after forming said conductor integrated in said conductor trench, the conformity is altered in order to close said contact trench with said conductive inner conductor layer.

12. The method of claim 7, comprising patterning said conductive outer conductor layer on said top side of said substrate surface.

13. The method of claim 8, wherein said conductor led to said top side of said substrate is led further coaxially on said top side of said substrate.

14. The method of claim 7, wherein said conductor is tubular or a coaxial conductor.
